(19) United States
(12) Patent Application Publication
(10) Pub. No.: US 2018/0211703 A1
(43) Pub. Date: Jul. 26, 2018

(54) HIGH-DENSITY 3D VERTICAL RERAM WITH BIDIRECTIONAL THRESHOLD-TYPE SELECTOR

(71) Applicant: Western Digital Technologies, Inc., San Jose, CA (US)

(72) Inventors: Won Ho Choi, San Jose, CA (US); Jay Kumar, Saratoga, CA (US); Daniel Bedau, San Jose, CA (US); Zvonimir Z. Bandic, San Jose, CA (US); Seung-Hwan Song, San Jose, CA (US)

(21) Appl. No.: 15/588,422

(22) Filed: May 5, 2017

Related U.S. Application Data
(60) Provisional application No. 62/449,528, filed on Jan. 23, 2017.

(51) Int. Cl. G11C 13/00

(52) U.S. Cl. CPC G11C 13/0038

(57) ABSTRACT

The present disclosure, in various embodiments, describes three-dimensional (3D) vertical resistive random access memory (ReRAM) structures. In one embodiment, a memory device includes a resistive memory element and a selector coupled in series with the resistive memory element. A turn-on voltage of the selector is greater than a bias voltage of the memory device in an unselected state such that the selector remains in a turn-off state when the memory device is unselected, and the selector is configured to have substantially the same resistance in both a forward bias direction and a reverse bias direction in a turn-on state.

### CROSS-REFERENCE TO RELATED APPLICATIONS

This application claims priority to and the benefit of U.S. Provisional Patent Application Ser. No. 62/449,528, filed 23 Jan. 2017, which is titled “HIGH-DENSITY 3D VERTICAL RERAM WITH BIDIRECTIONAL THRESHOLD-TYPE SELECTOR”, the entire contents of which are incorporated herein by reference.

### FIELD

The present disclosure, in various embodiments, relates to vertical memory structures and more particularly relates to three-dimensional (3D) vertical resistive random access memory (ReRAM) structures.

### BACKGROUND

In a variety of consumer electronics and computers, solid state data storage devices incorporating non-volatile memories (NVMs) are frequently replacing or supplementing conventional rotating hard disk drives for mass storage. Some memory architectures, such as one transistor one resistor (1T1R) architectures, may be relatively simple to implement, may have little or no disturb effects or sneak paths, and/or may have high parallelism, but may have a large footprint that makes scalability difficult. Such memory architectures may also be difficult or impossible to stack, to increase storage density, leading to higher cost, lower density storage.

A three dimensional (3D) memory array includes an array of memory cells that are vertically oriented or arranged such that a number of memory cells are vertically located or stacked over each other. Such vertical orientation of memory cells allows higher density of memory cells per unit area. One example of 3D memory arrays is a 3D vertical resistive random access memory (ReRAM) device, which may be used in NVMs to provide non-volatile data storage. A ReRAM device or cell contains a NVM material that has a resistance that can be controlled (e.g., a high conductive state and a low conductive state) to store data.

### SUMMARY

One embodiment of the present disclosure provides a memory device, for example, a resistive random access memory (ReRAM) device. The memory device includes a resistive memory element and a symmetrical bidirectional selector coupled in series with the resistive memory element. A turn-on voltage of the symmetrical bidirectional selector is greater than a bias voltage of the memory device in an unselected state. The memory device may be configured to be biased at a first voltage in a turn-on state and at a second voltage in a turn-off state that has a higher resistance than that of the turn-on state, and the turn-on voltage of the symmetrical bidirectional selector is greater than the second voltage. The turn-on voltage of the symmetrical bidirectional selector may be less than or equal to the first voltage of the memory device.

Another embodiment of the present disclosure provides a system that includes a memory array including a plurality of memory cells stacked in a vertical direction. In the memory array, a memory cell includes a resistive memory element and a selector coupled in series with the resistive memory element. A turn-on voltage of the selector is greater than a bias voltage of the memory cell in an unselected state, and the selector has substantially the same resistance in both a forward bias direction and a reverse bias direction during a turned-on state. The system further includes a controller operatively coupled to the memory array that is configured to select one or more of the memory cells for data access.

Another embodiment of the present disclosure provides a method for fabricating a memory device. The method provides a plurality of alternating dielectric layers and conductor layers on a substrate. Then method forms a plurality of openings traversing the plurality of alternating dielectric layers and conductors layers in a vertical direction. The method further forms two or more vertically stacked layers of memory cells in the plurality of openings. For each of the memory cells, the method forms a resistive memory element and a symmetrical bidirectional selector coupled in series with the resistive memory element. A turn-on voltage of the symmetrical bidirectional selector is greater than a bias voltage of the memory cells in an unselected state.

Another embodiment of the present disclosure provides a memory device that includes means for storing data utilizing a resistive memory element, and means for controlling a leakage current of the memory device coupled in series with the resistive memory element. The means for controlling a leakage current is configured to be in a non-conductive state when the resistive memory element is in an unselected state.

Another embodiment of the present disclosure provides a memory device that includes a resistive memory element and a selector coupled in series with the resistive memory element. A first voltage for placing the selector in a conductive state is greater than a second voltage for placing the memory device in an active but inaccessible state, wherein the selector, in the conductive state, is configured to have substantially the same resistance in both a forward bias direction and a reverse bias direction.

### BRIEF DESCRIPTION OF THE DRAWINGS

A more particular description is included below with reference to specific embodiments illustrated in the appended drawings. Understanding that these drawings depict only certain embodiments of the disclosure and are not therefore to be considered to be limiting of its scope, the disclosure is described and explained with additional specificity and detail through the use of the accompanying drawings, in which:

FIG. 1 is a schematic block diagram illustrating one embodiment of a system utilizing vertical three-dimensional (3D) resistive random access memory (ReRAM);

FIG. 2 is a schematic block diagram illustrating another embodiment of a system for vertical 3D ReRAM;

FIG. 3 is a schematic block diagram illustrating a cross-sectional view of a vertical 3D ReRAM architecture with bidirectional threshold-type selector according to a first embodiment;

FIG. 4 is a schematic block diagram illustrating a cross-sectional view of a vertical 3D ReRAM architecture with bidirectional threshold-type selector according to a second embodiment;

FIG. 5 illustrates an exemplary voltage-current graph of a bidirectional threshold type selector according to an embodiment of the disclosure;

FIG. 6 illustrates an exemplary graph of voltage versus component state for a memory cell including a selector according to an embodiment of the disclosure.

FIGS. 7-13 depict one embodiment of a process for fabricating a vertical 3D ReRAM structure with bidirectional threshold-type selectors according to one embodiment;

FIGS. 14 and 15 illustrate a method for fabricating a vertical 3D ReRAM structure with bidirectional threshold-type selectors according to one embodiment.

### DETAILED DESCRIPTION

In the following detailed description, reference is made to the accompanying drawings, which form a part thereof. In addition to the illustrative aspects, embodiments, and features described above, further aspects, embodiments, and features will become apparent by reference to the drawings and the following detailed description. The description of elements in each figure may refer to elements of proceeding figures. Like numbers may refer to like elements in the figures, including alternate embodiments of like elements.

Aspects of the present disclosure provide various apparatus, device, and methods for reducing leakage current in resistive random access memory (ReRAM). In one aspect, a ReRAM cell is provided with a bidirectional threshold-type selector that is connected in series with a resistive memory element such that leakage current through an unselected cell may be substantially reduced.

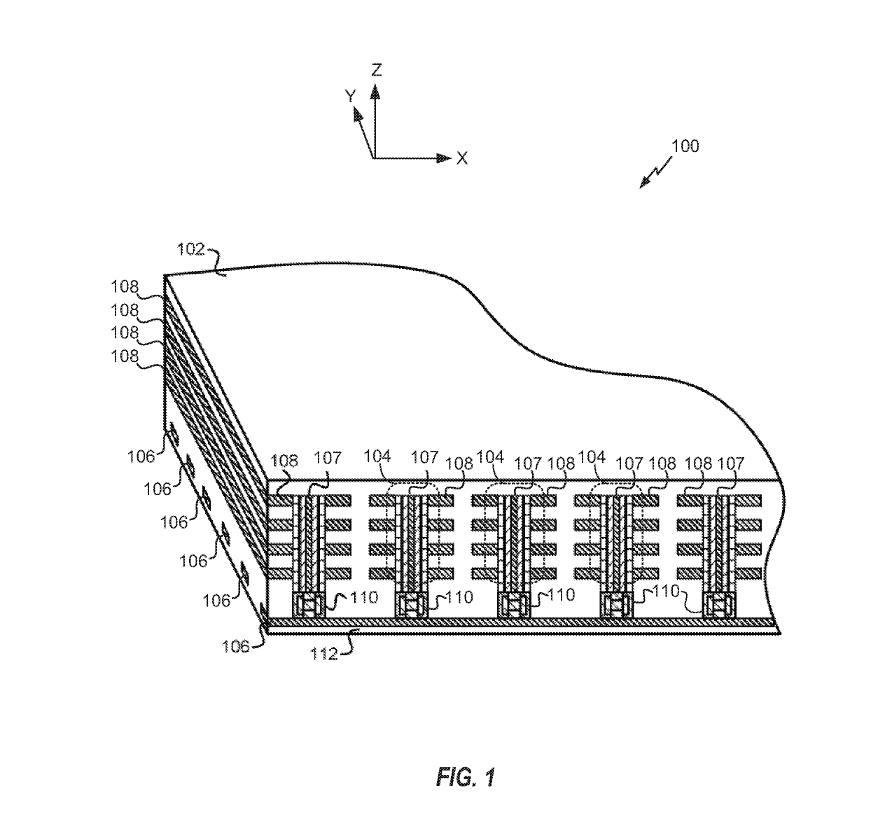

FIG. 1 depicts a cutaway perspective view of one embodiment of a system 100 for resistive random access memory (ReRAM). The system 100, in the depicted embodiment, includes one or more non-volatile memory elements 102, each comprising a substrate 112, a plurality of vertical memory structures 104, a plurality of global bit lines 106, a plurality of word lines 108, and a plurality of switches 110. In this example, the global bit lines 106 extend in the X direction, and the word lines 108 extend in the Y direction, as shown in FIG. 1. In some examples, the vertical memory structures 104 may be referred to as pillars extending in the Z direction in FIG. 1 and located at the crossings between the global bit lines 106 and word lines 108. Each of the vertical memory structures 104 has a vertical local bit line 107 that is coupled to a corresponding global bit line 106 via a switch 110.

In general, a non-volatile memory (NVM) element 102 comprises a non-volatile memory medium for storing data. The non-volatile memory element 102 may comprise and/or be part of a non-volatile memory device for storing data using an array of vertical three-dimensional (3D) memory structures 104, which may each comprise multiple two terminal memory cells of storage class memory, such as ReRAM or the like. For example, the system 100 may comprise one or more non-volatile memory elements 102, such as one or more chips, packages, dies, die planes, and/or other integrated circuit memory devices (e.g., one or more monolithic, three-dimensional memory devices; semiconductor devices; and/or other solid-state devices) comprising a non-volatile memory medium.

In one embodiment, a non-volatile memory element 102 comprises a plurality of ReRAM devices (e.g., a substrate 112 with an array of vertical 3D memory structures 104 comprising one or more layers of resistive memory material for storing data). A resistive memory material, as used herein, comprises a material with a resistance or conductivity that may be changed (e.g., high/low resistance or low/high conductivity). Some non-limiting examples of materials that may be used for fabricating ReRAM devices are phase-change chalcogenides (e.g., such as Ge₂Sb₂Te₅ or AgInSbTe, binary transition metal oxides (e.g., NiO or TiO), perovskites (e.g., Sr(Zr)TiO₃ or PCMO, solid-state electrolytes (e.g., GeS, GeSe, SiOx or Cu₂S), organic charge-transfer complexes such as CuTCNQ, and organic donor-acceptor systems such as Al AIDCN.

In one embodiment, two states of a ReRAM material may be used to store a single bit of data per cell (e.g., two states per cell, single level cell (SLC) memory, or the like). A state may correspond to a certain resistance value or range of the ReRAM material. In a further embodiment, more than two states of a ReRAM material may be used to store multiple bits of data per cell (e.g., multiple states per cell, multilevel cell (MLC) memory, triple level cell (TLC) memory, quadruple level cell (QLC) memory, or the like). For example, two bits of data may be stored using four states.

The non-volatile memory element 102 may comprise a substrate 112 or other base or support structure. For example, the substrate 112 may comprise a silicon wafer (e.g., mono-crystal silicon wafer, silicon on sapphire), a gallium arsenide wafer, ceramic, or the like. In certain embodiments, the substrate 112 comprises one or more electrical connections (e.g., one or more pins, pads, leads, contacts, traces, electrically conductive holes, or the like) for the non-volatile memory element 102 to interface with a printed circuit board, packaging, and/or another electrical interface.

Several integrated circuit layers, in certain embodiments, may be deposited or otherwise formed on the substrate 112 to form the non-volatile memory element 102. In the depicted embodiment, the non-volatile memory element 102 includes a plurality of electrically conductive word lines 108 and global bit lines 106, with electrically insulating material between the electrically conductive word lines 108 and bit lines (e.g., between adjacent word lines 108 in the same layer, between word lines 108 in different layers, between global bit lines 106, between local bit lines 107, between word lines 108 and global bit lines 106, and/or between other electrically conductive material of the non-volatile memory element 102). For example, the non-volatile memory element 102 may be formed with alternating layers of conductive material (e.g., metal) and insulating material (e.g., dielectric), or the like, using a masking process, a deposition process, and/or another similar process to form the word lines 108, bit lines 106, and other features and circuitry of the non-volatile memory element 102.

The vertical memory structures 104 (e.g., pillars) comprise a non-volatile memory medium, such as a resistive memory material or the like, for storing data. In certain embodiments, the vertical memory structures 104 may be formed using an iterative, layered deposition process with the layers of word lines 108 and/or bit lines 106. In a further embodiment, one or more memory holes (e.g., openings or cavities) may be formed in the non-volatile memory element 102 during the fabrication and/or manufacturing process, in which the vertical memory structures 104 may be deposited and/or otherwise formed. For example, memory holes or other openings may be preserved using a masking process (e.g., to prevent the deposition of electrically conductive material or electrically insulating material). Memory holes or other openings may be drilled, cut, etched, and/or otherwise formed after the layers of electrically conductive material and electrically insulating material have been deposited, or the like.

The vertical memory structures 104, in certain embodiments, are deposited or otherwise formed in memory holes or other openings in the layers of electrically conductive material and electrically insulating material on the substrate 112. Non-volatile memory cells, in one embodiment, are formed at the intersection of the word lines 108 and local bit lines 107. The vertical memory structures 104 form a three-dimensional (3D) array of non-volatile memory cells.

In one embodiment, a non-volatile memory medium of the vertical memory structures 104 (e.g., a resistive memory material or the like) and/or one or more other layers (e.g., a separation layer, a selector layer, a central bit line layer, or the like) may be deposited in a memory hole or other opening using an atomic layer deposition (ALD) process and/or another thin film or chemical vapor deposition (CVD) process. For example, a sequence of precursor chemicals (e.g., alternate gaseous species, or the like) may be exposed to a surface of the memory hole or other opening, which acts as a substrate upon which the intended layer is grown (e.g., a layer of phase change material or other non-volatile memory medium, a separation layer of carbon and/or an oxide, a selector layer of a different phase change material, a metallic central bit line layer, or the like). In one embodiment, multiple precursors may be used simultaneously. In another embodiment, different precursors may be inserted in a series of sequential, non-overlapping pulses, or the like. In certain embodiments, the precursor molecules react with the surface in a self-limiting way, so that the reaction terminates once all the reactive sites on the surface are consumed (e.g., an ALD cycle). In other embodiments, a direct liquid injection (DLI) vaporizer deposition process may be used, a physical vapor deposition (PVD) process may be used, or the like.

The vertical memory structures 104, in one embodiment, comprise multiple layers, such as a conductive bit line layer (e.g., a local bit line, a central bit line, a vertical bit line, or the like), a non-volatile memory medium layer (e.g., a resistive memory material layer, or the like), a selector layer, and/or another layer. In one embodiment, the selector layer may include an ovonic threshold-type switch material layer or the like. In the depicted embodiment, each vertical memory structure 104 may include a central, vertical, electrically conductive bit line, with a resistive memory material disposed on at least two sides of the bit line (e.g., on two opposite sides of the bit line; surrounding the bit line; or the like) as a non-volatile memory medium. One or more word lines 108, in the depicted embodiment, are in electrical communication with (e.g., in contact with) a selector layer (e.g., an ovonic threshold switch material), forming one or more memory cells between each word line 108 and an associated bit line.

The selector layer, in certain embodiments, may reduce and/or eliminate sneak path currents (leakage currents) that may cause disturb effects and/or higher currents, allowing for a larger memory array size (e.g., more memory cells and layers) than would be possible without the selectors. As used herein, a selector comprises a non-linear element (NLE) and/or a switching element in electrical communication with a non-volatile memory medium (e.g., a resistive memory material or the like) to provide electrical selectivity of different memory cells of the non-volatile memory medium.

In one embodiment, a selector comprises an ovonic threshold switch (OTS) or a non-linear volatile switch that may be formed of a phase change material. An ovonic threshold switch (OTS) may comprise a two-terminal symmetrical, voltage sensitive, switching device (e.g., current isolation device) comprising a chalcogenide and/or other phase change material, with at least a blocking state (non-conducting or high resistance) and a conducting state (low resistance), or the like. In response to a voltage potential between a word line 108 and a bit line exceeding a threshold voltage of the OTS selector for a corresponding non-volatile memory cell, the OTS becomes conductive, selecting the non-volatile memory cell and conducting electric current to the non-volatile memory cell. The OTS is symmetrical in the sense that it has substantially similar resistance or conductivity when current flows through the two terminals in different directions (e.g., forward and reverse directions). In some examples, the difference in resistance between the forward and reverse directions may be 5 percent or less. In one embodiment, the OTS may be referred to as a symmetrical bidirectional selector.

An ovonic threshold switch (OTS) selector, in various embodiments, may comprise a chalcogenide phase change material (e.g., an ovonic threshold switching material) such as AsTeGeSi, AsTeGeSiN, GeTe, GeSe, SiTe, ZnTe, GeTeSbAs, GeSbTe, and/or one or more other combinations of these elements (e.g., other combinations of As, Te, Ge, Si, N, Se, Zn, or the like). In various embodiments, the OTS selector may be made of a material that is different from the non-volatile memory medium of a memory cell. A phase change material used for a selector (e.g., an ovonic threshold switching material), in one embodiment, has a higher melting point and/or phase change point than a melting point and/or phase change point of a phase change material used as a non-volatile memory medium of a memory cell (e.g., ReRAM). In this manner, in certain embodiments, the selector maintains its properties (e.g., resistance or conductivity) and does not change states or phases during normal operation (e.g., typical temperatures, voltages, and/or currents) of the non-volatile memory element 102, even when the non-volatile memory medium changes states or resistance. The selector when implemented with an OTS material has characteristics (e.g., bidirectional threshold-type switching, symmetry switching, and non-linear switching) that are not available in other types of selectors such as a poly junction selector (e.g., a Si PN junction or the like), an oxide junction selector (e.g., an Ox PN junction or the like), an oxide rectifier, a mixed-ionic-electronic-conduction (MIEC) based selector (e.g., Cu+ in SE or the like), a metal-insulator-metal (MIM) junction, a metal-insulator-semiconductor (MIS) junction, a metal-semiconductor (MS) Schottky junction, or the like.

In the depicted embodiment, the non-volatile memory medium (e.g., a resistive memory material) and the symmetric bidirectional OTS selector are connected in series between a word line 108 and a bit line 106, and may be directly formed next to each other. In some embodiments, a conductive intermediate layer or electrode may be formed between the resistive memory material and the selector. In some embodiments, the relative positions of the OTS selector and the non-volatile memory medium may be reversed between the corresponding word line and bit line. For example, the OTS selector may be directly connected to the bit line, and the non-volatile memory medium may be directly connected to the word line.

To write data to a resistive memory element, a first write current may be used to write a first logical value (e.g., a value corresponding to a high-resistance state) to the resistive memory element, and a second write current may be used to write a second logical value (e.g., a value corresponding to a low-resistance state) to the resistive memory element. The different write currents may be generated by applying different voltages across the resistive memory element by applying different voltages across the corresponding bit line and word line.

While a resistive material (e.g., ReRAM) is used herein as the primary embodiment of a non-volatile memory medium of the non-volatile memory element 102, in other embodiments the non-volatile memory element 102 may comprise PCM, Memristor memory, programmable metallization cell memory, phase-change memory, NAND flash memory (e.g., 2D NAND flash memory, 3D NAND flash memory), NOR flash memory, nano random access memory (nano RAM or NRAM), nanocrystal wire-based memory, silicon-oxide based sub-10 nanometer process memory, graphene memory, Silicon-Oxide-Nitride-Oxide-Silicon (SONOS) memory, programmable metallization cell (PMC) memory, conductive-bridging RAM (CBRAM), magneto-resistive RAM (MRAM), or the like. The non-volatile memory medium of the non-volatile memory element 102, in certain embodiments, may comprise a storage class memory (SCM).

While legacy technologies such as NAND flash may be block and/or page addressable, storage class memory, in one embodiment, is byte addressable. In further embodiments, storage class memory may be faster and/or have a longer life (e.g., endurance) than NAND flash; may have a lower cost, use less power, and/or have a higher storage density than DRAM; or offer one or more other benefits or improvements when compared to other legacy technologies. For example, storage class memory may comprise one or more non-volatile memory elements 102 of phase-change memory, ReRAM, Memristor memory, programmable metallization cell memory, nano RAM, nanocrystal wire-based memory, silicon-oxide based sub-10 nanometer process memory, graphene memory, SONOS memory, PMC memory, CBRAM, MRAM, and/or variations thereof.

In the depicted embodiment, each vertically oriented 3D resistive memory element comprises memory cells at the cross-points of the word lines 108 and bit lines 106 (e.g., the horizontal global bit lines 106; the vertical, central, and/or local bit lines within a vertical memory structure 104; or the like). In this manner, several memory cells (e.g., 2 memory cells, 4 memory cells, 8 memory cells, 16 memory cells, 32 memory cells, 64 memory cells, or the like) may be implemented by a single continuous layer of material (e.g., phase change material). For example, in the depicted embodiment, strips of resistive memory material or other non-volatile memory material are oriented vertically along opposite sides of the vertical memory structure 104, with 4 word lines 108 on each opposite side as well to form the memory cells. In certain embodiments, word lines 108 and strips of insulating material under them in a group of planes may be defined simultaneously by use of a single mask, thus simplifying the manufacturing process.

In the depicted embodiment, planes comprising the word lines 108 have substantially the same horizontal pattern of conductive, insulating, and resistive memory materials. In each plane, electrically conductive (e.g., metal) word lines 108 (e.g., WLzx) are elongated in a first direction and spaced apart in a second direction. Each plane includes a layer of insulating material (e.g., a dielectric) that isolates the plane's word lines 108 from the word lines 108 of the plane below it and/or of the substrate 112 circuit components below it. In some embodiments, the word lines 108 WLzx for a fixed value of x form a stack of alternating layers that may extend beyond the memory element 102 into a contact area (not shown), or the like.

Extending through each plane, in the depicted embodiment, is an array of electrically conductive (e.g., metal) local bit line (LBL) “pillars” within each vertical memory structure 104 (e.g., a central, vertical bit line), elongated in the vertical direction, perpendicular to the word lines 108. Each vertical memory structure 104 (e.g., through the associated internal local bit line pillar) is connected to one of a set of underlying global bit lines (GBL) 106 (e.g., located in the silicon substrate 112) running horizontally (e.g., in a parallel plane to the word lines 108, but elongated in a different, perpendicular direction than the word lines 108), at the same pitch as a pillar spacing of the vertical memory structures 104, connected through the switch devices 110. The switch devices 110 selectively place the global bit lines 106 in electric communication with the vertical, central, local bit lines within the vertical memory structures 104. For example, the switch devices 110 may comprise transistors (e.g., vertically oriented field effect transistors), one of the selector devices described above, and/or another type of switch. The switch devices 110 may be formed in or on the substrate 112. The switch devices 110 may have gates driven by row select lines (SG) (e.g., also formed in the substrate or the like). Also fabricated in or on the substrate 112, in certain embodiments, may be sense amplifiers, input-output (I/O) circuitry, control circuitry, and/or other peripheral circuitry. There may be one row select line (SG) for each row of vertical memory structures 104 (e.g., pillars) and one select device (Q) for each individual local bit line (LBL) within each vertical memory structure 104.

Each resistive memory element is sandwiched between a vertical local bit line (LBL) and a word line (WL) that correspond to the resistive memory element. As described above, in certain embodiments, a bidirectional threshold switching selector layer (e.g., comprising a different phase change material such as an OTS material) may be disposed between the word line 108 and the resistive memory material or between the resistive memory material and the local bit line. In this manner, in certain embodiments, a memory cell is located at each intersection of a word line 108 and a local bit line 107 (e.g., with a vertical stack of memory cells at intersections of the word lines 108 and the global bit lines 106), which may controllably be alternated between more resistive and less resistive states by appropriate currents and/or voltages applied to the intersecting lines to store or read data. Using bidirectional threshold-type selectors and the switch devices 110, in one embodiment, the non-volatile memory element 102 may be bit addressable with reduced leakage current in a high density 3D configuration.

While the non-volatile memory medium is referred to herein as “memory medium,” in various embodiments, the non-volatile memory medium may generally comprise one or more non-volatile recording media capable of recording data, which may be referred to as a non-volatile memory medium, a non-volatile storage medium, or the like. Further, the non-volatile memory element 102, in various embodiments, may comprise and/or be referred to as a non-volatile recording element, a non-volatile storage element, or the like.

The non-volatile memory element 102, in various embodiments, may be disposed in one or more different locations relative to the computing device or other host. In one embodiment, the non-volatile memory element 102 may comprise one or more semiconductor die, chips, packages, and/or other integrated circuit devices disposed on one or more printed circuit boards, storage device housings, and/or other mechanical and/or electrical support structures. For example, one or more non-volatile memory elements 102 may be disposed on one or more direct inline memory module (DIMM) cards, one or more expansion cards and/or daughter cards, a solid-state-drive (SSD) or other hard drive device, and/or may have another memory and/or storage form factor. The non-volatile memory element 102 may be integrated with and/or mounted on a motherboard of a computing device, installed in a port and/or slot of a computing device, installed on a remote computing device and/or a dedicated storage appliance on a data network, may be in communication with a computing device over an external bus (e.g., an external hard drive), or the like.

The non-volatile memory element 102, in one embodiment, may be disposed on a memory bus of a processor (e.g., on the same memory bus as volatile memory, on a different memory bus from volatile memory, in place of volatile memory, or the like). In a further embodiment, the non-volatile memory element 102 may be disposed on a peripheral bus of a computing device, such as a peripheral component interconnect express (PCI Express or PCIe) bus, a serial Advanced Technology Attachment (SATA) bus, a parallel Advanced Technology Attachment (PATA) bus, a small computer system interface (SCSI) bus, a FireWire bus, a Fibre Channel connection, a Universal Serial Bus (USB), a PCIe Advanced Switching (PCIe-AS) bus, or the like. In another embodiment, the non-volatile memory element 102 may be disposed on a data network, such as an Ethernet network, an Infiniband network, SCSI RDMA over a network, a storage area network (SAN), a local area network (LAN), a wide area network (WAN) such as the Internet, another wired and/or wireless network, or the like.

A non-volatile memory controller may be communicatively coupled to the non-volatile memory element 102 by way of a bus, may be part of the same integrated circuit and/or package as the non-volatile memory element 102, or the like. A bus may comprise an I/O bus for communicating data to/from the non-volatile memory elements 102. A bus may comprise a control bus for communicating addressing and/or other command or control information to the non-volatile memory elements 102. In some embodiments, a bus may communicatively couple multiple non-volatile memory elements 102 to a non-volatile memory controller in parallel. This parallel access may allow multiple non-volatile memory elements 102 to be managed as a group, forming a logical memory element or the like. A logical memory element may be partitioned into respective logical memory units (e.g., logical pages) and/or logical memory divisions (e.g., logical blocks). The logical memory units may be formed by logically combining physical memory units of each of the non-volatile memory elements.

A non-volatile memory controller may organize a block of word lines 108 within a non-volatile memory element 102, in certain embodiments, using addresses of the word lines, such that the word lines are logically organized into a monotonically increasing sequence (e.g., decoding and/or translating addresses for word lines into a monotonically increasing sequence, or the like). In a further embodiment, word lines 108 within a non-volatile memory element 102 may be physically arranged in a monotonically increasing sequence of word line addresses, with consecutively addressed word lines also being physically adjacent (e.g., WL0, WL1, WL2, . . . WLN). In other embodiments, different addressing systems may be used.

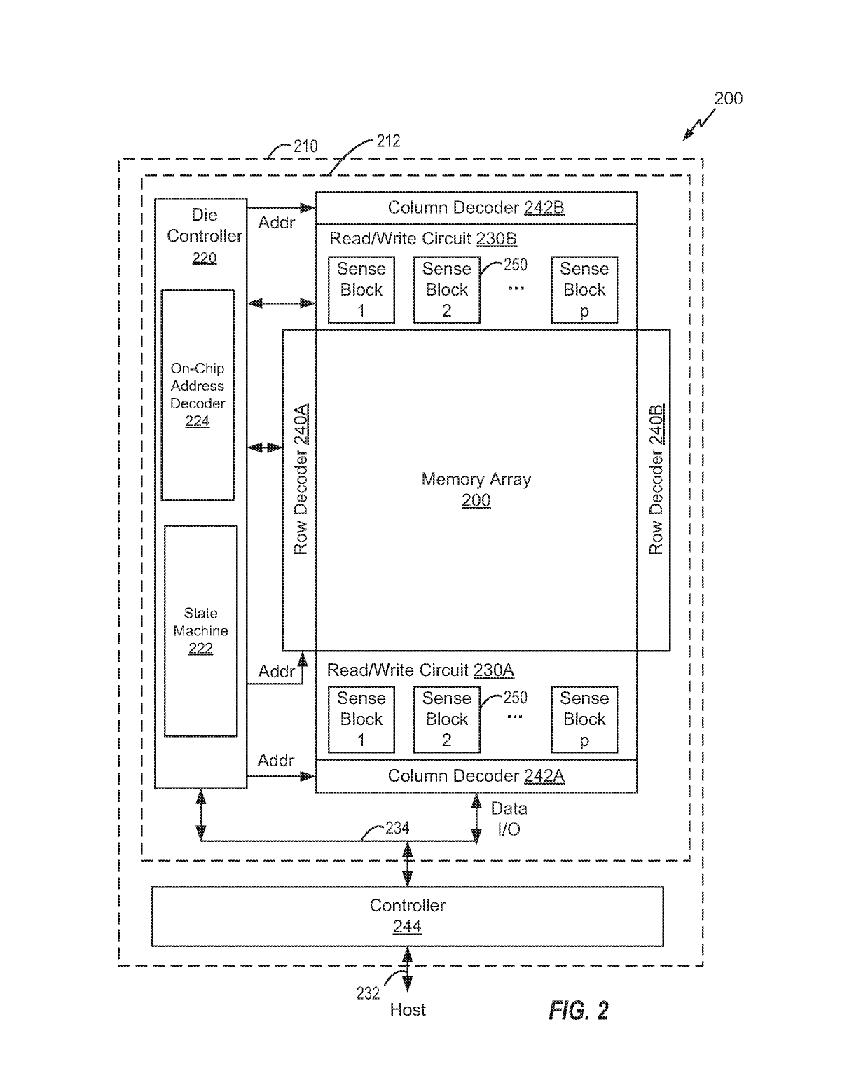

FIG. 2 depicts one embodiment of a system using vertical 3D ReRAM. The system, in the depicted embodiment, includes a non-volatile storage device 210. A non-volatile storage device 210 may include one or more memory die or chips 212, which may be substantially similar to the non-volatile memory element 102 of FIG. 1. A memory die 212, in the depicted embodiment, includes an array of memory cells 200 (e.g., a three-dimensional array of vertical memory structures 104 as described above with regard to FIG. 1, or the like), a die controller 220, and read/write circuits 230A/230B. In one embodiment, access to the memory array 200 by the various peripheral circuits is implemented in a symmetric fashion, on opposite sides of the array, so that the densities of access lines and circuitry on each side are reduced by half. The read/write circuits 230A/230B, in a further embodiment, include multiple sense blocks 250, which allow a page or block of memory cells to be read or programmed in parallel.

The memory array 200, in various embodiments, is addressable by word lines 108 via row decoders 240A/240B and by bit lines 106 via column decoders 242A/242B. In some embodiments, a controller 244 is included in the same memory device 210 (e.g., a removable storage card or package) as the one or more memory die 212. Commands and data are transferred between the host and controller 244 via lines 232 and between the controller and the one or more memory die 212 via lines 234. One implementation can include multiple chips 212.

Die controller 220, in one embodiment, cooperates with the read/write circuits 230A/230B to perform memory operations or data access on the memory array 200. The die controller 220, in certain embodiments, includes a state machine 222, and an on-chip address decoder 224.

The state machine 222, in one embodiment, provides chip-level control of memory operations. The on-chip address decoder 224 provides an address interface to convert between the address that is used by the host or a memory controller to the hardware address used by the decoders 240A, 240B, 242A, 242B. In one embodiment, one or any combination of die controller 220, decoder circuit 224, state machine circuit 222, decoder circuit 242A, decoder circuit 242B, decoder circuit 240A, decoder circuit 240B, read/write circuits 230A, read/write circuits 230B, and/or controller 244, can be referred to as one or more managing circuits.

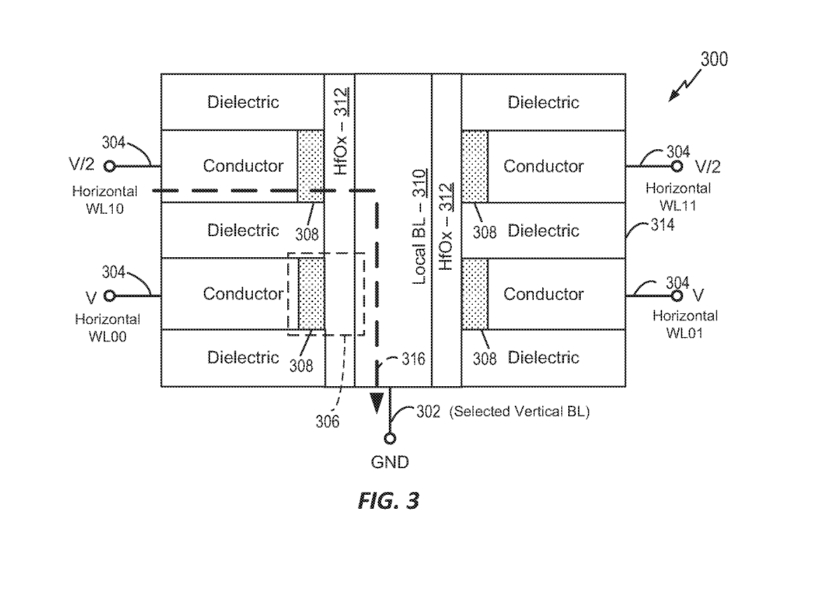

FIG. 3 depicts a cross-sectional view of a 3D vertical ReRAM architecture 300 with bidirectional OTS selectors according to an embodiment. In certain embodiments, the depicted bit line 302, word lines 304, resistive memory cells 306, and bidirectional OTS selectors 308 may be substantially similar to those described above with regard to FIGS. 1 and 2. In one embodiment, the bidirectional OTS selectors 308 may be referred to as the symmetrical bidirectional selectors described in this specification. A memory cell 306 may be accessed (read or write) by applying voltages (e.g., V/2, V, GND) across the bit line 302 and a corresponding word line 304.

A local bit line conductor 310 (e.g., local BL 310) extending vertically is disposed central to the ReRAM architecture 300. A layer of resistive memory material 312 is disposed on at least two sides of the local bit line conductor 310 and may be implemented with vertical strips on two opposite sides (as shown), on three sides, on four sides, or the like. In one such embodiment, the layer of resistive memory material 312 may circumscribe the local bit line conductor 310. At each projected intersection of the local bit line conductor 310 and a word line 304, the resistive memory material 312 forms a resistive memory cell (e.g., resistive memory cell 306), which may also be referred to as a resistive memory element. In some embodiments, the resistive memory element may include HfOₓ and/or other suitable resistive memory materials. The local bit line conductor 310 may be a local bit line that is electrically coupled to the vertical bit line 302. Between the layers of resistive memory material 312 and the word lines 304, in the depicted embodiment, are layers of a bidirectional OTS selector material 308, which act as selectors for the memory cells 306 formed by the resistive memory material 312. In the depicted embodiment, the resistive memory material 312 comprises a continuous vertical strip along the length of the local bit line conductor 310, while the OTS selector materials 308 are separated or isolated in the vertical direction by non-conductive dielectric layers 314. In some embodiments, the resistive memory material 312 may be separated or isolated in the vertical direction. In one example, the dielectric layers 314 may comprise SiO₂ or other dielectric material.

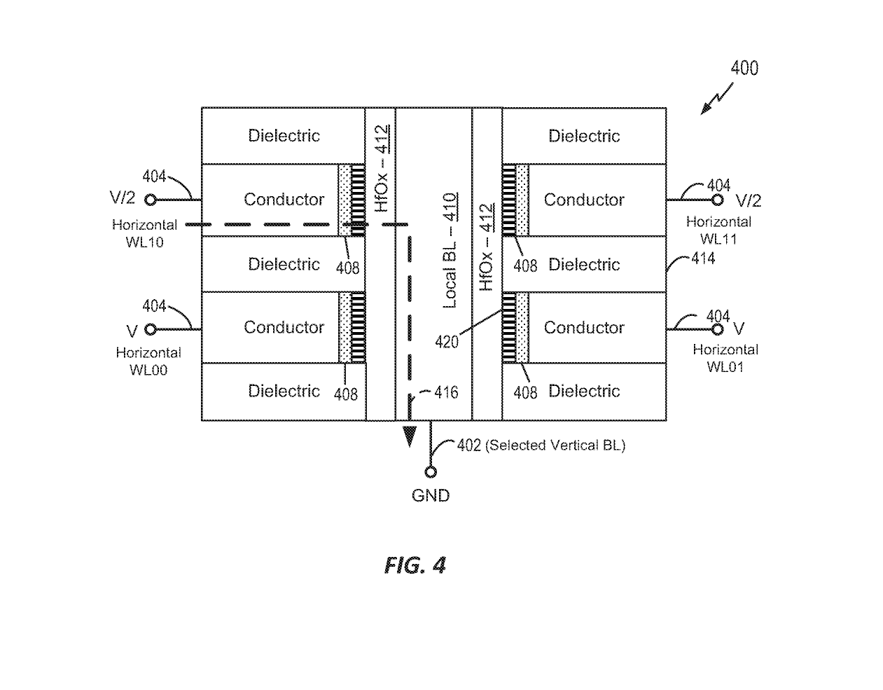

FIG. 4 is a schematic block diagram illustrating a cross-sectional view of a vertical 3D ReRAM architecture 400 with bidirectional threshold-type selector according to a second embodiment. In this embodiment, an intermediate layer or electrode 420 may be disposed between the resistive memory material 412 and the OTS selector 408. In one embodiment, the bidirectional OTS selectors 408 may be referred to as the symmetrical bidirectional selectors described in this specification. The intermediate layer 420 can provide various functions and benefits. For example, the intermediate layer can spread the electrical current when the selector and/or memory cell is filamentary. In one embodiment, the intermediate layer 420 can function as an adhesion layer, diffusion barrier, or seed layer. In one embodiment, the intermediate layer 420 can separate chemically incompatible layers (e.g., incompatible OTS layer and resistive memory material 412). In one embodiment, the intermediate layer 420 can include a material that can reduce interdiffusion of adjacent layers. In one embodiment, the intermediate layer 420 can prevent adjacent layers from mechanical delamination. In one embodiment, the intermediate layer 420 can provide thermal insulation, or it can serve as a nucleation/seed layer to improve the grows of further layers deposited after the intermediate layer. In one embodiment, the intermediate layer 420 can limit current (e.g., excessive current) through the resistive memory material 412. In this manner, in the depicted embodiment, a word line 404, an OTS selector 408, a resistive memory material 412, and a bit line conductor 402 are electrically coupled in series, forming a two-terminal memory cell 406. Multiple memory cells are formed along opposite sides of the local bit line conductor 410 in a vertical, 3D array. In one embodiment, the intermediate layer 420 may include metals, for example, Pd, Ag, Ti, Zr, Hf, Mo, Co, and/or alloys thereof such as CrCu, BiCu, TiMo, and TiW. In one embodiment, the intermediate layer 420 may include semiconductors, for example, Si, Ge and/or alloys thereof. In one embodiment, the intermediate layer 420 may include conductive oxides, for example, simple oxides, TiO2, HfO2. In one embodiment, the intermediate layer 420 may include perovskites and/or nitrides, for example, TaN, TiN, silicides (e.g., PtSi, or PdSi), borides, and/or carbides.

The bidirectional OTS selectors 308 and 408 are configured to suppress or reduce leakage current and the associated voltage drop during memory read/write operations. Therefore, read/write disturb effects and raw bit error rate (RBER) may be reduced. Higher memory density can be achieved with the OTS selector's higher selectivity because the aggregated leakage current of the memory cells can be reduced using the OTS selector as described in this disclosure. Without the OTS selector, a leakage current (e.g., leakage currents 316 and 416 in FIGS. 3 and 4) may flow through an unselected cell. That is, because a particular bias voltage is used to place a memory cell in the unselected state, the leakage current 416 may flow from a wordline (e.g., wordline 304) to a local bit line (e.g., local bit line 310) or vice-versa. This leakage current may be undesirable for the reasons described above. The unselected cell refers to a cell that is not biased with a voltage (bias voltage) that enables the cell for data access (i.e., read or write). The bias voltage is applied across the wordline and bit line connected to the cell that includes the OTS selector.

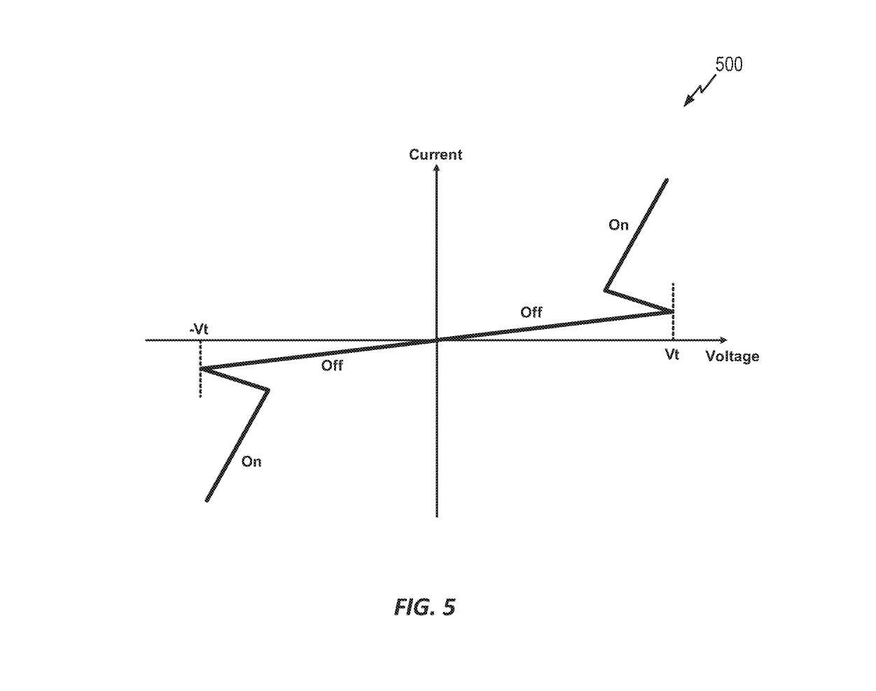

FIG. 5 illustrates an exemplary voltage-current graph 500 of a bidirectional threshold type selector according to an embodiment of the disclosure. In this embodiment, the OTS selector 308 or 408 may have a positive threshold voltage Vt and a negative threshold voltage −Vt. In one example, −Vt may be −1V and Vt may be 1V. In other embodiments, the threshold voltage may have other values. Within the range between −Vt and Vt (e.g., −1V to 1V), the OTS selector remains in the its “off” or non-conductive state (high resistance). Therefore, when unselected memory cells are biased within this voltage range in a turn-off state, their bidirectional OTS selectors remain “off” in a turn-off state. Thus the bidirectional OTS selectors can reduce or block the leakage currents through the unselected cells. When a cell is selected, it can be biased with a voltage outside of the threshold voltage range of the OTS selector such that the selector is in a conductive state (turn-on state).

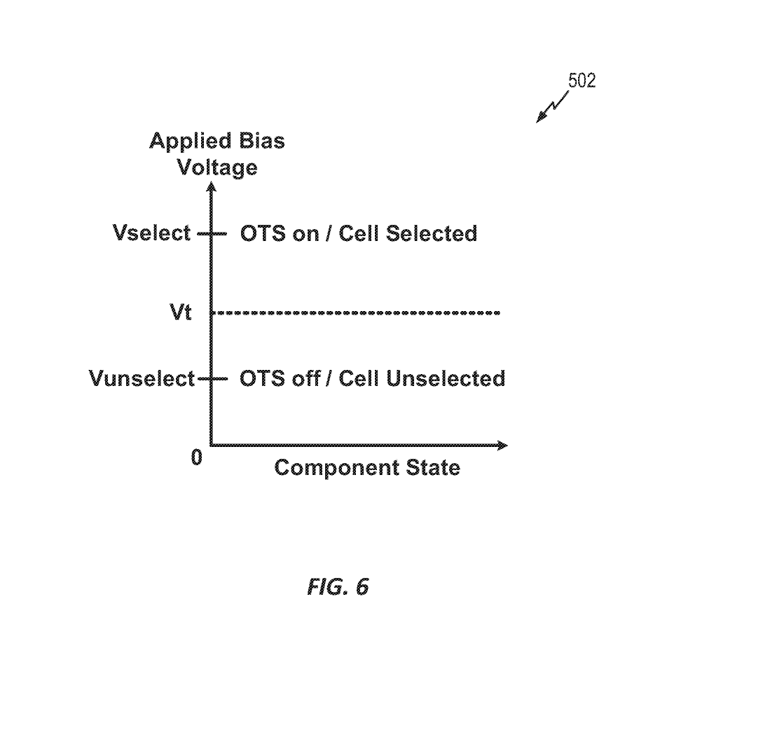

FIG. 6 also illustrates an exemplary graph 502 of voltage versus component state for a memory cell including an OTS selector according to an embodiment of the disclosure. When the voltage applied to the cell is zero, the OTS is turned off and the cell is unselected. When a voltage (V_{unselect}) that is lower than Vt is applied across the wordline and bit line of a memory cell, the OTS selector remains off and the cell is still unselected. In one aspect, this V_{unselect} or turn-off voltage with respect to the cell, is sufficient to put the cell in an unselected state, which is an active but inaccessible state. When a voltage (V_{select}) that is higher than Vt is applied, the OTS selector is turned “on” and the cell is selected. In one aspect, this V_{select} or turn-on voltage with respect to the OTS, is sufficient to turn on the OTS, and thereby put it in a conductive state. When the OTS selector is turned “on” (i.e., turned-on state), the selector is in a conductive state that has relatively low resistance as compared to the turned-off state. In conventional memory cells, which do not include an OTS in a series configuration, a leakage current can occur at V_{unselect} where the cell is not selected. This is because a non-zero voltage is applied to the cell and no switch (e.g., OTS) is present to prevent the leakage current at V_{unselect}. In contrast, the memory cell with an OTS at the same voltage V_{unselect}, as shown in FIG. 6, can prevent a leakage current as the OTS is switched off. In one embodiment, the Vt may be referred to as a first voltage, and Vunselect may be referred to as a second voltage, where the first voltage is greater than the second voltage.

In some embodiments, the OTS selector may be referred to as bidirectional in that it allows current to flow in a forward direction and reverse direction when the OTS selector is in the turn-on state. In some embodiments, the OTS selector may be referred to as symmetrical because the voltage-current response of the OTS selector is substantially symmetrical such that the resistance of the OTS selector is substantially the same when current flows in either direction (e.g., forward direction and reverse direction) through the OTS selector.

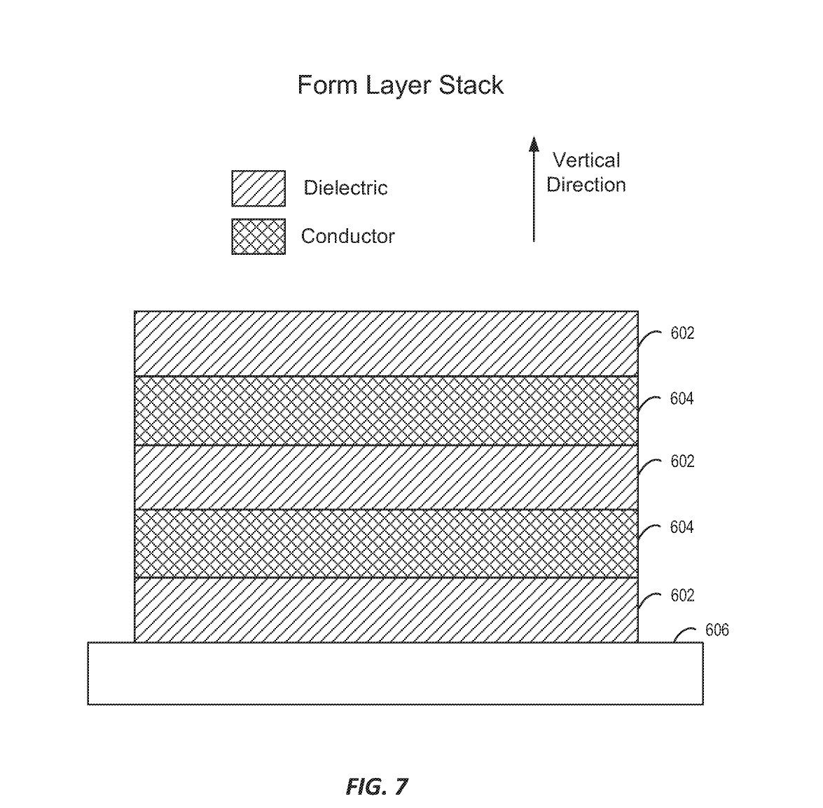

FIGS. 7-13 depict one embodiment of a method for fabricating a vertical 3D ReRAM with symmetrical bidirectional OTS selectors. Referring to FIG. 7, a manufacturing process, device, apparatus, or system is used to form a stack of dielectric layers 602 and conductor layers 604 on a substrate 606. In other embodiments, more or less dielectric layers and/or conductor layers may be formed than those shown in FIG. 7. In this example, a first dielectric layer 602 is first formed on the substrate 606, and a conductor layer 604 is formed on the first dielectric layer 602. Then, additional dielectric layers and conductor layers may be formed alternately. In some embodiments, other layers of material (not shown) may be formed between a dielectric layer 602 and a conductor layer 604.

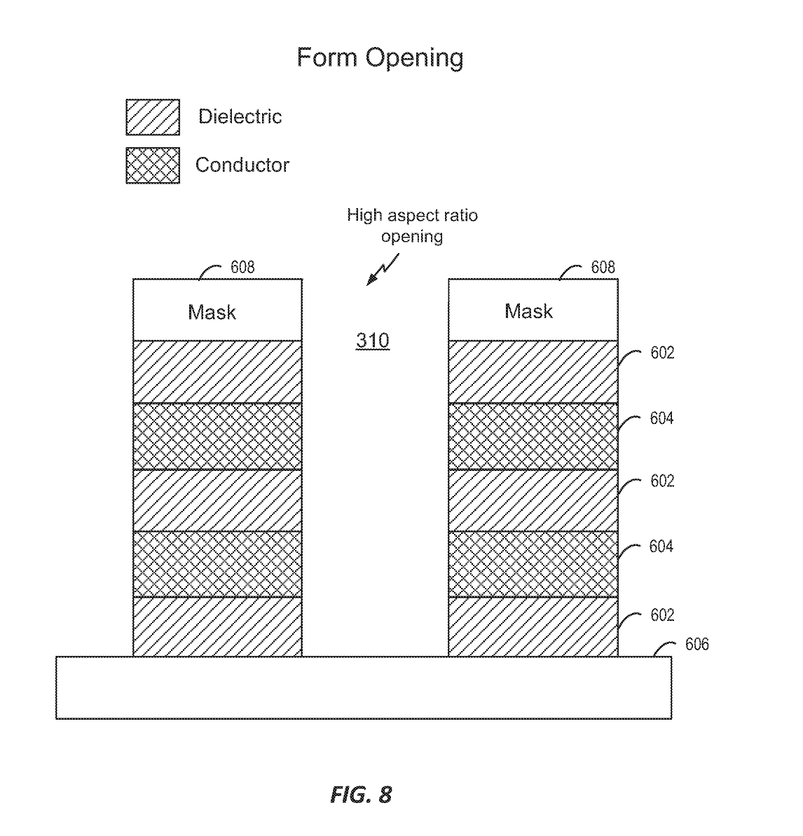

Referring to FIG. 8, a manufacturing device forms a mask 608 (e.g., a hard mask) on top of the stack of FIG. 7 and performs an etching process (e.g., “deep hole etching”) to create a high aspect ratio opening 610 through the stack. In one example, the aspect ratio may between about 2:1 or higher. The mask 608 may be removed after etching the opening 610. In one example, the etching process may be a plasma etch process.

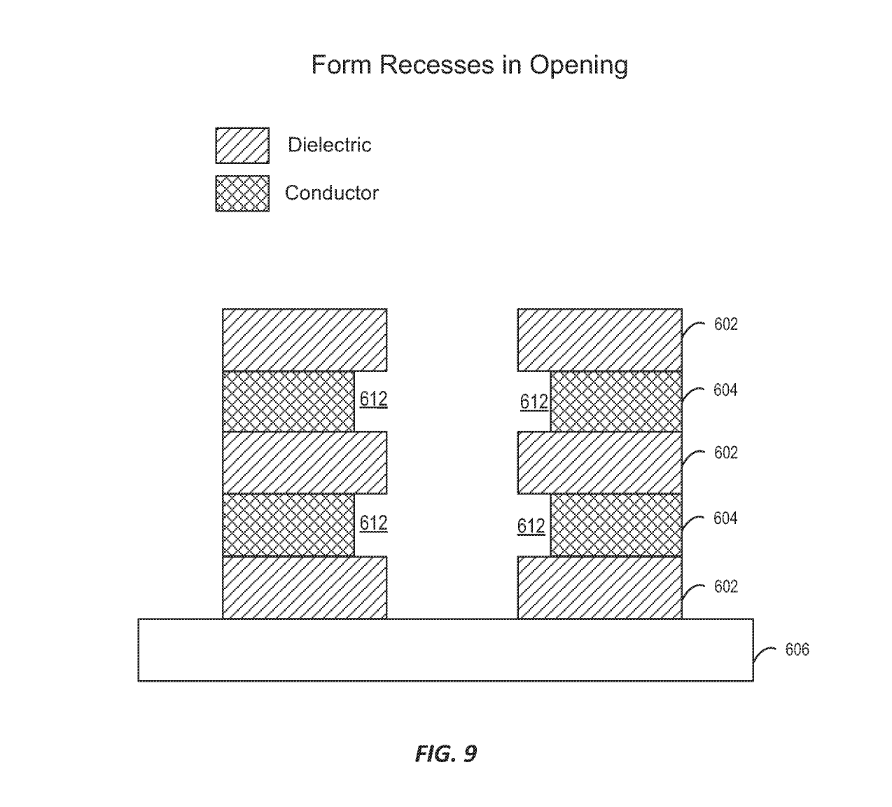

Referring to FIG. 9, a manufacturing device performs a selective etching process to each the conductor layers 604 to create a plurality of recesses 612 or cavities between the dielectric layers 602. In some examples, the selective etching process may be a recess etching process, which can be a wet or dry etching process. During the selective etching process, some portions of the conductor layers 604 are removed between dielectric layers. In some examples, the recesses may have a depth between about 0 nm and about 50 nm.

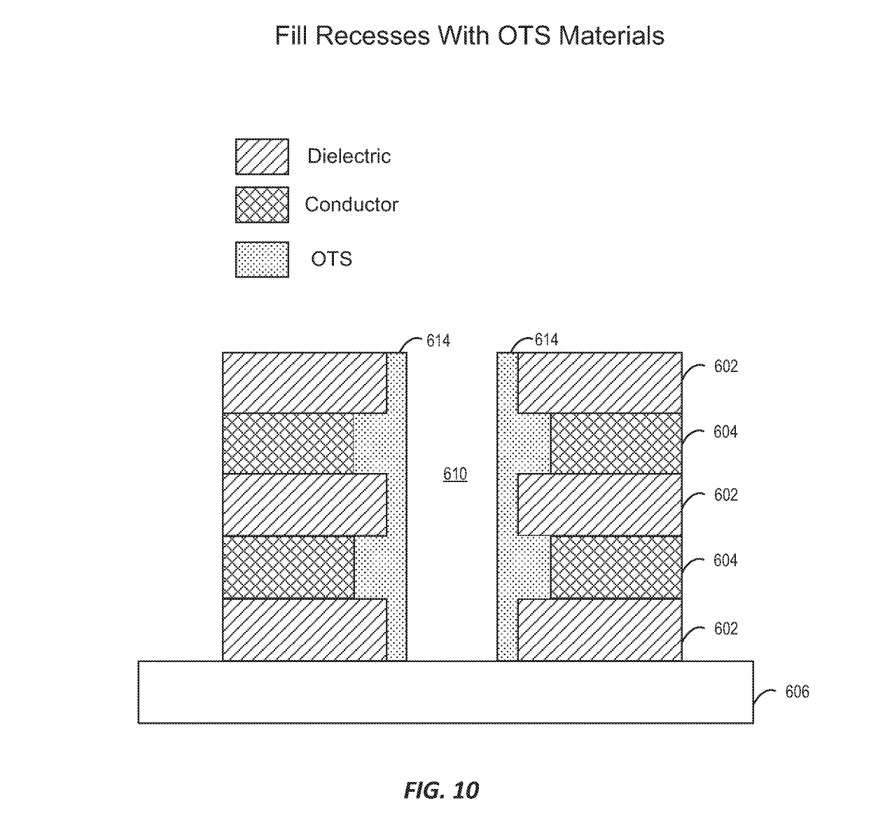

Referring to FIG. 10, a manufacturing device performs a deposition process to fill the recesses 612 with a bidirectional OTS selector material 614 or the like. In some embodiments, a selective ALD (Atomic Layer Deposition) process or the link may be used to deposit the OTS selector material into the recesses 612. In some examples, more bidirectional OTS selector material 614 may be deposited into the recesses 612 than on the dielectric surface facing the central opening 610. Therefore, the bidirectional OTS selector material 614 may have different thicknesses along the vertical direction of the stack or vertical ReRAM.

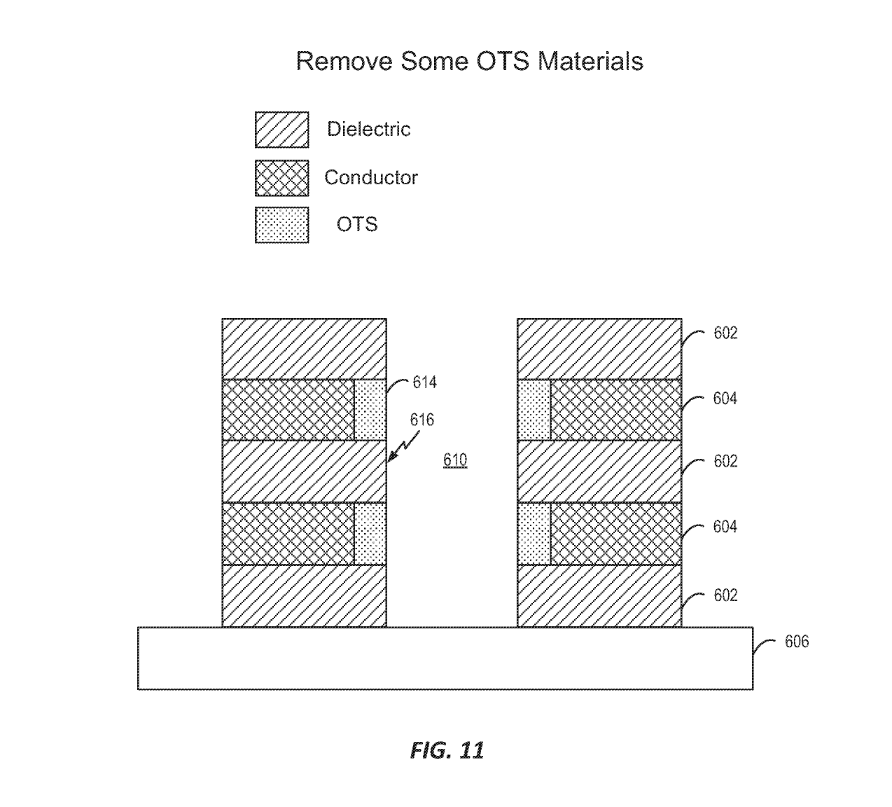

Then, referring to FIG. 11, some of the deposited OTS selector material 614 may be removed from the dielectric surface, and thus the surfaces 616 of the dielectric layers 602 may be exposed and face toward the center opening 610. In this example, the remaining individual portions of OTS selector material 614 may form a substantially flush surface with the dielectric layers in the opening 610. In some examples, the OTS material may have a thickness between about 5 nm and about 50 nm.

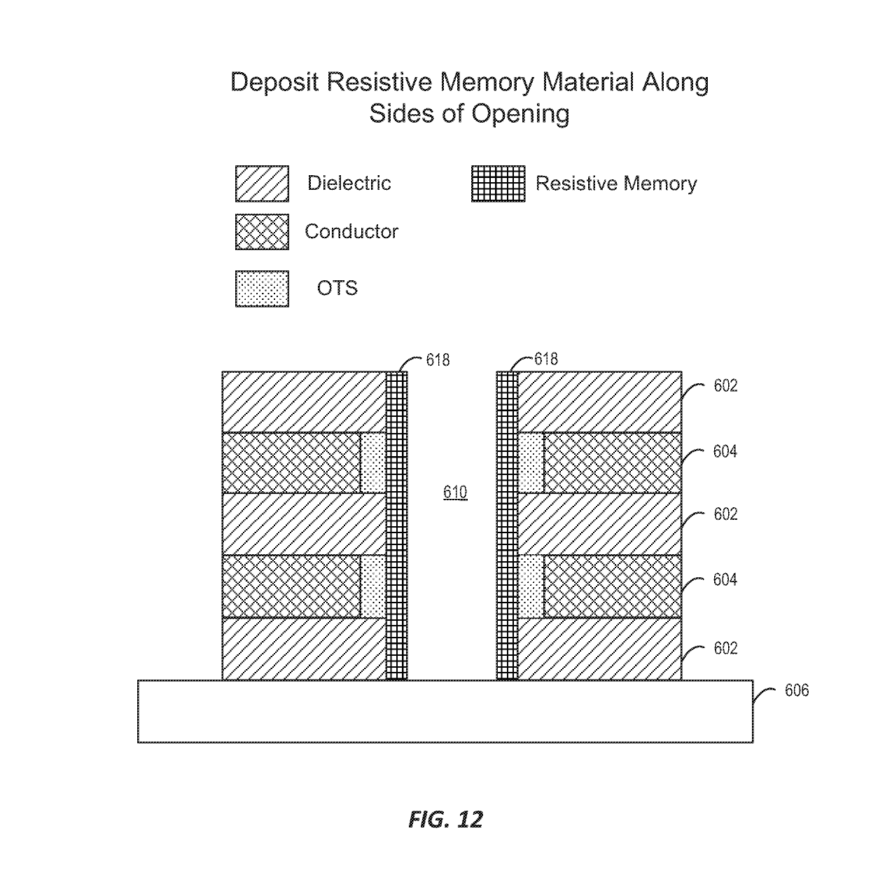

Referring to FIG. 12, a manufacturing device may deposit a resistive memory material (e.g., HfOₓ or other resistive memory material) into the opening 610 to form a resistive memory layer 618 covering the dielectric layers 602 and OTS selector materials 614. In one embodiment, the resistive memory layer 618 may be deposited using ALD or CVD (Chemical Vapor Deposition). In some examples, the memory layer may have a thickness between about 1 nm and about 20 nm.

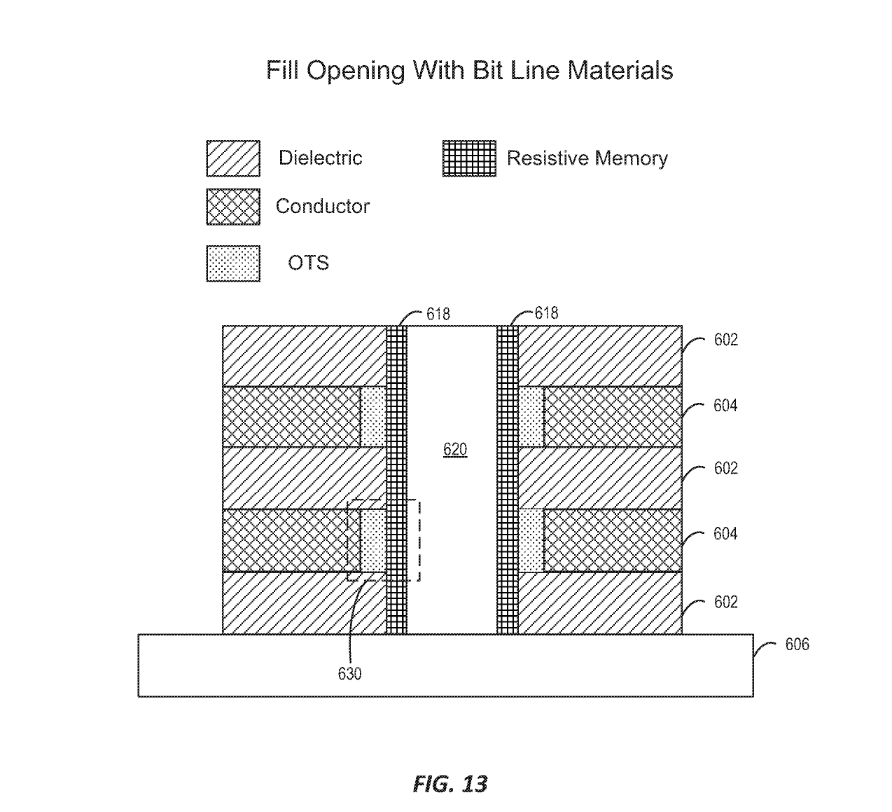

Referring to FIG. 13, a manufacturing device may fill the center opening with a conductive material 620 to form the vertical bit line. Therefore, a plurality of ReRAM cells (an exemplary ReRAM cell 630 is illustrated in FIG. 13) are formed each having an OTS selector. In some embodiments, the conductive material 620 may be a conductive polysilicon (poly), polymer, or other conductive material. In some examples, the conductive material may be deposited by CVD or ALD.

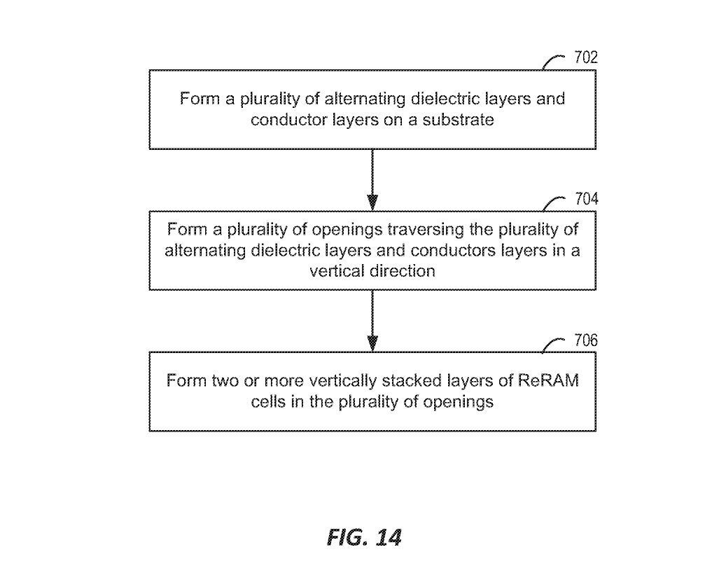

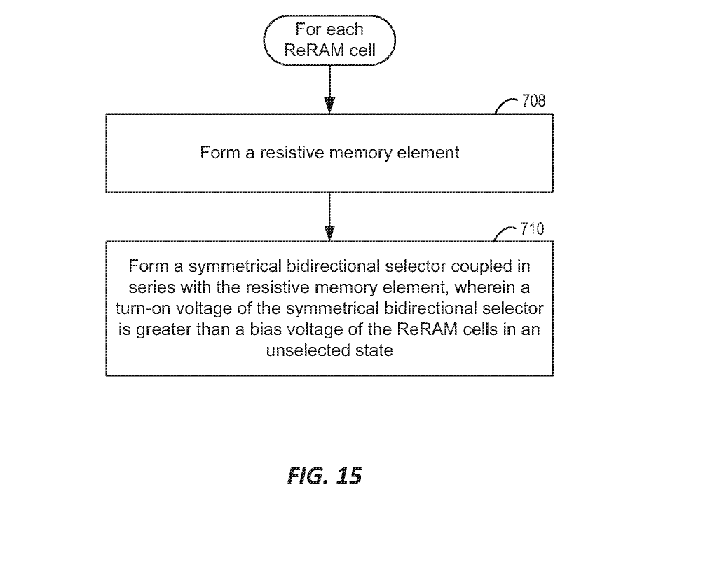

FIGS. 14 and 15 illustrate a method for fabricating a vertical 3D ReRAM according to an embodiment. For example, this method may be utilized to fabricate the vertical 3D ReRAM with symmetrical bidirectional OTS selectors as described above in relation to FIGS. 3-13. Referring to FIG. 14, at block 702, the method forms a plurality of alternating dielectric layers 602 and conductor layers 604 on a substrate 606. At block 704, the method forms a plurality of openings 610 traversing the plurality of alternating dielectric layers and conductor layers in a vertical direction. At block 706, the method forms two or more vertically stacked layers of ReRAM cells (e.g., ReRAM cells 630 in FIG. 13) in the plurality of openings. Referring to FIG. 15, for each ReRAM cell, the method forms a resistive memory element at block 708. The resistive memory element may be formed using a resistive memory material such as HfOx or the like. At block 710, the method forms a symmetrical bidirectional selector coupled in series with the resistive memory element.

In one embodiment, a turn-on voltage of the symmetrical bidirectional selector is greater than a bias voltage of the ReRAM cells in an unselected state. The bias voltage is a voltage applied across the read line and write line coupled to a ReRAM cell during various operations. For example, a ReRAM memory cell can be selected for reading/writing or unselected by applying different bias voltages (e.g., read voltage, write voltage, unselected voltage). When a ReRAM memory cell is unselected or in an unselected state, data cannot be read from or written to the cell. That is the cell is prevented from being accessed (e.g., for read or write access). In this unselected state, the ReRAM memory cell may not be in a floating state where no voltage is applied thereto (see e.g., voltage V1 in FIG. 6 for unselected state versus voltage of zero where the memory cell may be off or floating). Rather, the ReRAM memory cell may be in an active state where a voltage sufficient for maintaining the unselected state is applied. In such case, the cell may be in an active but inaccessible state. In the inaccessible state, data cannot be read from or written to the cell. When the cell is in an accessible state, data may be read from and/or written to the cell. The turn-on voltage for the symmetrical bidirectional selector refers to a voltage that when applied across the read line and write line coupled to the ReRAM cell containing the selector (and thereby across the symmetrical bidirectional selector), causes the selector to maintain a conductive state or turn-on state (see e.g., voltage V2 in FIG. 6). The conductive or turn-on states may be defined by a low resistance across the selector. In some embodiments, the turn-on voltage may be generated by the read/write circuits 230A/230B described in relation to FIG. 2.

Using the above-described processes illustrated in FIGS. 7-15, a vertical 3D ReRAM with low leakage current can be fabricated. In these embodiments, the bias voltage of the unselected memory cells is within a turn-on threshold voltage range (e.g., −1V to 1V) of the bidirectional OTS selectors or similar selectors. Therefore, the selectors coupled to the unselected cells will remain turned-off (i.e., non-conducting or high resistance) while selected memory cells are biased with a voltage higher than the threshold voltage of the selector. As such, the leakage current through the unselected memory cells can be significantly reduced or blocked. By reducing the leakage current, more layers of memory cells may be fabricated in a vertical 3D ReRAM. Moreover, tighter bit line pitch may be used to increase cell density. Lower leakage current can also reduce read/write disturb and raw bit error rate.

Aspects of the present disclosure may be embodied as an apparatus, system, method, or computer program product. Accordingly, aspects of the present disclosure may take the form of an entirely hardware embodiment or an embodiment combining software and hardware aspects that may all generally be referred to herein as a “circuit,” “module,” “apparatus,” or “system.” Furthermore, aspects of the present disclosure may take the form of a computer program product embodied in one or more non-transitory computer readable storage media storing computer readable and/or executable program code.

Computer program code for carrying out operations for aspects of the present disclosure may be written in any combination of one or more programming languages, including an object-oriented programming language such as Python, Java, Smalltalk, C++, C#, Objective C, or the like, conventional procedural programming languages, such as the “C” programming language, scripting programming languages, and/or other similar programming languages. The program code may execute partly or entirely on one or more of a user's computer and/or on a remote computer or server over a data network or the like.

A component, as used herein, comprises a tangible, physical, non-transitory device. For example, a component may be implemented as a hardware logic circuit comprising custom VLSI circuits, gate arrays, or other integrated circuits; off-the-shelf semiconductors such as logic chips, transistors, or other discrete devices; and/or other mechanical or electrical devices. A component may also be implemented in programmable hardware devices such as field programmable gate arrays, programmable array logic, programmable logic devices, or the like. A component may comprise one or more silicon integrated circuit devices (e.g., chips, die, die planes, packages) or other discrete electrical devices, in electrical communication with one or more other components through electrical lines of a printed circuit board (PCB) or the like. Each of the modules described herein, in certain embodiments, may alternatively be embodied by or implemented as a component.

Reference throughout this specification to “one embodiment,” “an embodiment,” or similar language means that a particular feature, structure, or characteristic described in connection with the embodiment is included in at least one embodiment of the present disclosure. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Aspects of the present disclosure are described below with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated figures. Although various arrow types and line types may be employed in the flowchart and/or block diagrams, they are understood not to limit the scope of the corresponding embodiments. For instance, an arrow may indicate a waiting or monitoring period of unspecified duration between enumerated steps of the depicted embodiment.

While the above description contains many specific embodiments of the invention, these should not be construed as limitations on the scope of the invention, but rather as examples of specific embodiments thereof. Accordingly, the scope of the invention should be determined not by the embodiments illustrated, but by the appended claims and their equivalents.

The various features and processes described above may be used independently of one another, or may be combined in various ways. All possible combinations and sub-combinations are intended to fall within the scope of this disclosure. In addition, certain method, event, state or process blocks may be omitted in some implementations. The methods and processes described herein are also not limited to any particular sequence, and the blocks or states relating thereto can be performed in other sequences that are appropriate. For example, described tasks or events may be performed in an order other than that specifically disclosed, or multiple may be combined in a single block or state. The example tasks or events may be performed in serial, in parallel, or in some other suitable manner. Tasks or events may be added to or removed from the disclosed example embodiments. The example systems and components described herein may be configured differently than described. For example, elements may be added to, removed from, or rearranged compared to the disclosed example embodiments.

What is claimed is:

1. A memory device comprising:
a resistive memory element; and
a symmetrical bidirectional selector coupled in series with the resistive memory element,
wherein a turn-on voltage of the symmetrical bidirectional selector is greater than a bias voltage of the memory device in an unselected state.

2. The memory device of claim 1,
wherein the memory device is configured to be biased at a first voltage in a turn-on state and at a second voltage in a turn-off state that has a higher resistance than that of the turn-on state, and
wherein the turn-on voltage of the symmetrical bidirectional selector is greater than the second voltage.

3. The memory device of claim 2, wherein the turn-on voltage of the symmetrical bidirectional selector is less than or equal to the first voltage of the memory device.

4. The memory device of claim 1, wherein when the symmetrical bidirectional selector is turned-on, the symmetrical bidirectional selector is configured to allow current flow in a forward bias direction and a reverse bias direction that have substantially the same resistance in both directions.

5. The memory device of claim 1, further comprising:
a bit line coupled to the resistive memory element; and
a word line coupled to the symmetrical bidirectional selector such that the bit line, the resistive memory element, the symmetrical bidirectional selector, and the word line are coupled in series.

6. The memory device of claim 1, further comprising an intermediate electrode between the symmetrical bidirectional selector and the resistive memory element.

7. The memory device of claim 6, wherein the intermediate electrode comprises a material selected from the group consisting of Pd, Ag, Ti, Zr, Hf, Mo, Co, CrCu, BiCu, TiMo, TiW, Si, Ge, TiO2, HfO2, TaN, TiN, PtSi, PdSi, borides and carbides.

8. The memory device of claim 7, wherein the intermediate electrode and the symmetrical bidirectional selector comprise different materials.

9. The memory device of claim 1, wherein the symmetrical bidirectional selector comprises an ovonic threshold switch (OTS) comprising a chalcogenide phase change material selected from the group consisting of AsTeGeSi, AsTeGeSiN, GeTe, GeSe, and ZnTe.

10. A system comprising:
a memory array comprising a plurality of memory cells stacked in a vertical direction, wherein a memory cell of the plurality of memory cells comprises:
a resistive memory element; and
a selector coupled in series with the resistive memory element,
wherein a turn-on voltage of the selector is greater than a bias voltage of the memory cell in an unselected state, and the selector has substantially the same resistance in both a forward bias direction and a reverse bias direction during a turned-on state; and
a controller operatively coupled to the memory array, and configured to select one or more of the memory cells for data access.

11. A memory device comprising:
means for storing data utilizing a resistive memory element; and
means for controlling a leakage current of the memory device coupled in series with the resistive memory element, wherein the means for controlling a leakage current is configured to be in a non-conductive state when the resistive memory element is in an unselected state,
wherein a turn-on voltage of the means for controlling the leakage current is greater than a bias voltage of the memory device in an unselected state.

12. The memory device of claim 11,
wherein the memory device is configured to be biased at a first voltage in a turn-on state, and
wherein a turn-on voltage of the means for controlling the leakage current is less than or equal to the first voltage.

13. The memory device of claim 11, further comprising an intermediate electrode between the means for controlling the leakage current and the resistive memory element.

14. The memory device of claim 13, wherein the intermediate electrode comprises a material selected from the group consisting of Pd, Ag, Ti, Zr, Hf, Mo, Co, CrCu, BiCu, TiMo, TiW, Si, Ge, TiO2, HfO2, TaN, TiN, PtSi, PdSi, borides and carbides.

15. The memory device of claim 13, wherein the intermediate electrode and the means for controlling the leakage current comprise different materials.

16. A memory device comprising:
a resistive memory element; and
a selector coupled in series with the resistive memory element, wherein a first voltage for placing the selector in a conductive state is greater than a second voltage for placing the memory device in an active but inaccessible state,
wherein the selector, in the conductive state, is configured to have substantially the same resistance in both a forward bias direction and a reverse bias direction.

17. The memory device of claim 16,
wherein the memory device is biased to be accessible at a third voltage and to be inaccessible at a fourth voltage, and
wherein the first voltage of the selector is greater than the fourth voltage.

18. The memory device of claim 17, wherein the first voltage of the selector is less than or equal to the third voltage of the memory device.

19. The memory device of claim 16, wherein when the selector is in the conductive state, the selector is configured to allow current flow in a forward bias direction and a reverse bias direction.

20. The memory device of claim 16, further comprising:
a bit line coupled to the resistive memory element; and
a word line coupled to the selector such that the bit line, the resistive memory element, the selector, and the word line are coupled in series.

21. The memory device of claim 16, further comprising an intermediate electrode between the selector and the resistive memory element.

22. The memory device of claim 21, wherein the intermediate electrode comprises a material selected from the group consisting of Pd, Ag, Ti, Zr, Hf, Mo, Co, CrCu, BiCu, TiMo, TiW, Si, Ge, TiO2, HfO2, TaN, TiN, PtSi, PdSi, borides and carbides.

23. The memory device of claim 21, wherein the intermediate electrode and the selector comprise different materials.

24. The memory device of claim 16, wherein the selector comprises an ovonic threshold switch (OTS) comprising a chalcogenide phase change material selected from the group consisting of AsTeGeSi, AsTeGeSiN, GeTe, GeSe, and ZnTe.

25. The memory device of claim 16, further comprising:
a first conductor coupled to the selector; and
a second conductor coupled the resistive memory element;
wherein the first voltage and the second voltage are each applied across the selector coupled in series with the resistive memory element via the first and second conductors.
